(19) United States
(12) Patent Application Publication
(10) Pub. No.: US 2011/0109336 A1
(43) Pub. Date: May 12, 2011

(54) POSITIONING METHOD AND APPARATUS FOR INSPECTING SOLAR BATTERY PANEL

(76) Inventors: Yu-Hsing LIN, Taoyuan (TW); Jin-Po Tsa, Taoyuan County (TW); Che-Min Lin, Taoyuan County (TW); Po-Wen Peng, Taoyuan (TW)

(21) Appl. No.: 12/613,606

(22) Filed: Nov. 6, 2009

(51) Int. Cl. G01R 31/02; G01R 31/20

(52) U.S. Cl. 324/750.18; 324/761.01

(57) ABSTRACT

In a positioning method and apparatus capable of preventing a solar battery panel from suffer damage during inspection, the method includes steps of providing a transport platen, a set of positioning device, a first probe row and a second probe row; transporting the solar battery panel to an inspecting region by the transport platen; moving the positioning devices to position the solar battery panel step by step; the first probe row pressing an electrode line on one surface of the solar battery panel; the second probe row pressing an electrode line on the other surface of the solar battery panel, thereby electrically connecting the first probe row and the second probe row. In this way, the solar battery panel can be inspected accurately without suffering damage.

### BACKGROUND OF THE INVENTION

1. Field of the Invention

The present invention relates to a method for inspecting a solar battery panel, and in particular to an apparatus for inspecting solar battery panels.

2. Description of Prior Art

Since the solar energy is inexhaustible in supply and always available for use, more and more people pay attention to the solar energy. In order to utilize the solar energy, solar battery panels are used to absorb the sunlight and convert it into electricity. Thus, the manufacture of the solar battery panels has become a sunrise industry.

FIG. 1 shows an inspecting platen for a solar battery panel of prior art. During the inspection, the solar battery panel 10a is disposed on a conveyor belt 20a. An electrode line is provided on the solar battery panel 10a. The solar battery panel 10a is transported by the conveyor belt 20a to an inspecting region 100a. The inspecting region 100a is further provided with a plurality of probes (not shown). After both sides of the solar battery panel 10a are positioned in the inspecting region 100a, the probes press the electrode lines of the solar battery panel 10a, thereby measuring the voltage and current outputted by the solar battery panel 10a.

However, in practice, when the conveyor belt 20a transports the solar battery panel 10a to the inspecting region 100a, the solar battery panel 10a will be inevitably positioned with a little error, so that the center of the solar battery panel 10a cannot be aligned with the center of the inspecting region 100a correctly. At this time, these probes cannot press the electrode lines of the solar battery panel 10a correctly. Thus, when the conveyor belt 20a transports the solar battery panel 10a to the inspecting region 100a, both sides of the inspecting region 100a are provided with a set of positioning means 30a. The set of positioning means 30a presses both sides of the solar battery panel 10a to allow the solar battery panel 10a to be positioned into the inspecting region 100a.

However, since the solar battery panel 10a is light, thin and fragile, the edges of the solar battery panel 10a may suffer damage if the set of positioning means 30a push and position the solar battery panel 10a quickly. Further, the solar battery panel 10a may become warped after being baked in an oven. As a result, the probes may not contact the electrode lines on the surface of the solar battery panel 10a correctly.

Therefore, in order to overcome the above problems, the present Inventor proposes a reasonable and novel structure based on his delicate researches and expert experiments.

### SUMMARY OF THE INVENTION

The present invention is to provide a positioning method and apparatus for inspecting a solar battery panel, whereby the warping of the solar battery panel can be avoided and the electrode lines can be contacted completely.

The present invention is to provide a positioning method and apparatus for inspecting a solar battery panel, wherein the positioning process is executed step by step to reduce the pressure exerted by the positioning devices to the edges of the solar battery panel, thereby reducing the damage of the solar battery panel caused by the contact-type inspection.

The present invention is to provide a positioning method for inspecting a solar battery panel. Two opposite surfaces of the solar battery panel are provided with an electrode line respectively. The method includes steps of: a) providing a transport platen, a set of positioning devices, a first probe row and a second probe row; b) transporting the solar battery panel to an inspecting region by the transport platen; c) moving the set of positioning devices to position the solar battery panel; d) the first probe row pressing one surface of the solar battery panel, thereby positioning the first probe row to the electrode line on the surface of the solar battery panel; e) after the pressing of the first probe row is executed, the second probe row pressing the other surface of the solar battery panel, thereby positioning the second probe row to the electrode line on the other surface of the solar battery panel; and f) electrically connecting the first probe row and the second probe row to inspect the solar battery panel.

The present invention is to provide a positioning apparatus for inspecting a solar battery panel. Two opposite surfaces of the solar battery panel are provided with an electrode line respectively. The inspecting apparatus includes a transport platen for transporting the solar battery panel to an inspecting region; a set of positioning devices movable on both sides of the solar battery panel to position the solar battery panel into the inspecting region; a first probe row provided in the inspecting region for pressing electrode line on one surface of the solar battery panel; and a second probe row provided in the inspecting region for pressing electrode line on the other surface of the solar battery panel.

In comparison with prior art, the present invention has advantageous features as follows. Since the first probe row and the second probe row are activated to press one after another, the warped solar battery panel can be pressed flat, so that the first and second probe rows contact the electrode lines sufficiently, thereby measuring the voltage and current outputted by the electrode lines accurately. Further, the positioning devices position the solar battery panel in the inspecting region step by step. Elastic positioning means of cushioning property is used to reduce the pressure on the edge of the solar battery panel, thereby reducing the damage of the solar battery panel generated during the inspection. Thus, the yield is improved and the practicability of the present invention can be increased.

### BRIEF DESCRIPTION OF THE DRAWINGS

FIG. 1 is a schematic view showing an inspecting platen for the solar battery panel of prior art;

FIG. 2 is a flow chart showing the positioning method for inspecting the solar battery panel according to the present invention;

FIG. 3 is a plan view showing the inspecting apparatus of the present invention;

FIG. 4 is a side view showing the inspecting apparatus of the present invention;

FIG. 5 is a schematic view showing the transporting of the inspecting apparatus of the present invention;

FIG. 6 is a schematic view showing the basic positioning means of the inspecting apparatus of the present invention;

FIG. 7 is a schematic view showing the elastic positioning means of the inspecting apparatus of the present invention;

FIG. 8 is a schematic view showing the pressing of the first probe row of the inspecting apparatus of the present invention;

FIG. 9 is a schematic view showing the basic positioning means of the inspecting apparatus of the present invention is removed;

FIG. 10 is a schematic view showing the elastic positioning means of the inspecting apparatus of the present invention is removed;

FIG. 11 is a schematic view showing the pressing of the second probe row of the inspecting apparatus of the present invention; and

FIG. 12 is a schematic view showing the probe row assembly of the inspecting apparatus of the present invention is removed.

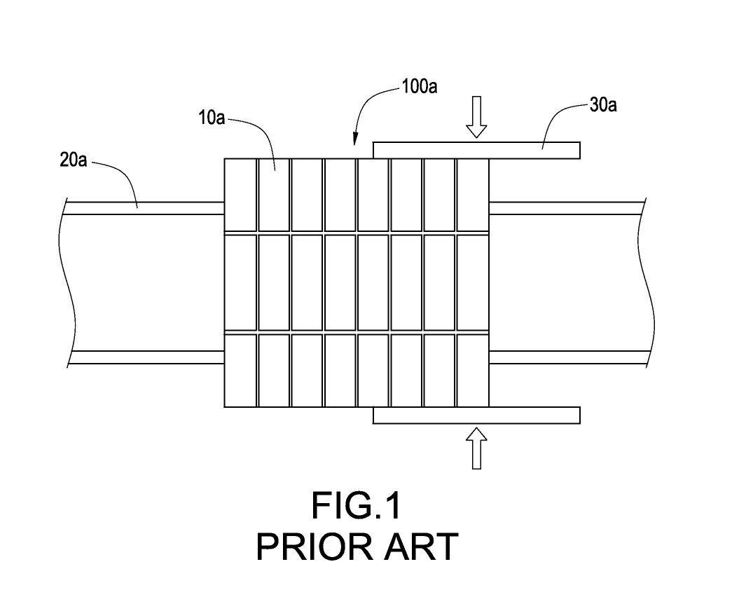

### DETAILED DESCRIPTION OF THE INVENTION

The characteristics and technical contents of the present invention will be explained with reference to the accompanying drawings. However, the drawings are illustrative only but not used to limit the present invention.

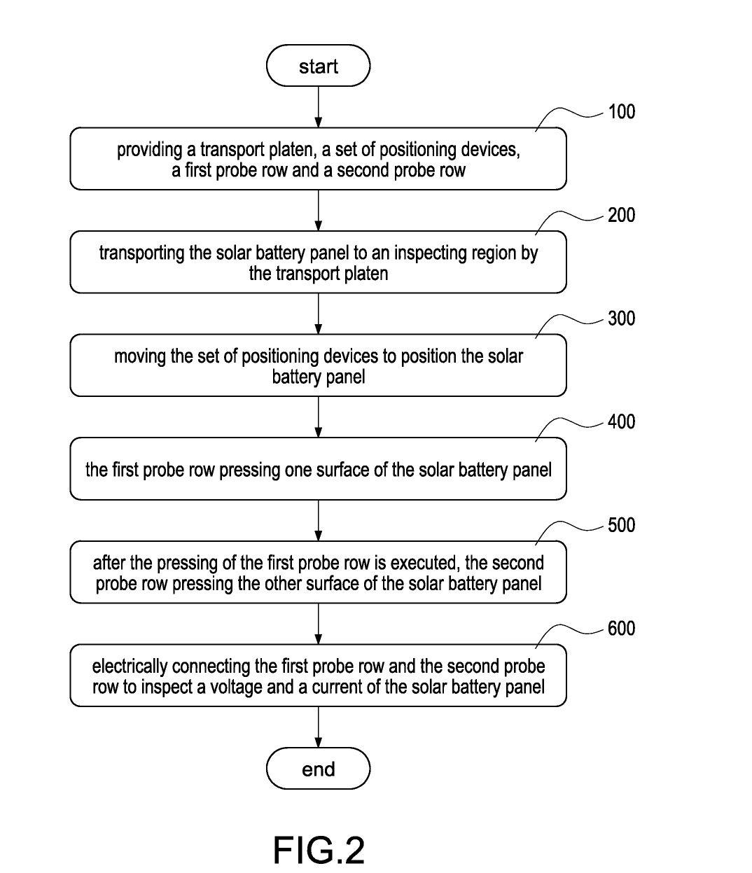

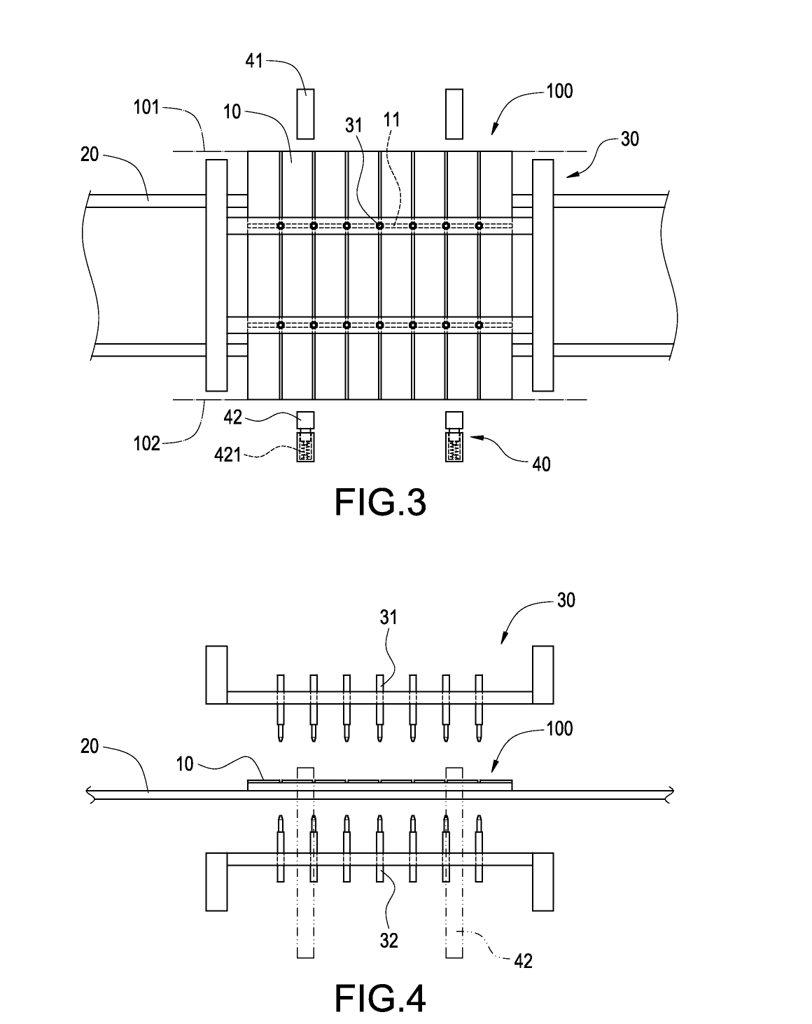

Please refer to FIGS. 2 to 4. FIG. 2 is a flow chart showing the positioning method for inspecting a solar battery panel according to the present invention. FIGS. 3 and 4 are a plan view and a side view showing the inspecting apparatus of the present invention respectively. The present invention provides a method for inspecting a solar battery panel 10, which begins with a step of providing a transport platen 20, a probe row assembly 30 and a set of positioning devices 40 (step 100).

Two opposite surfaces of the solar battery panel 10 are provided with an electrode line 11 respectively. The transport platen 20 may be a conveyor platen, a platen driven by a motor screw or a platen driven by a cylinder. The transport platen 20 transports the solar battery panel 10 to an inspecting region 100. The set of positioning devices 40 can be a positioning device driven by a motor screw or cylinder. The set of positioning devices 40 include a basic positioning means 41 and an elastic positioning means 42, which are provided on the opposite sides of the inspecting region 100 respectively. The elastic positioning means 42 is provided with an elastic element 421. The elastic element 421 may be a spring. The elastic element 421 cushions the elastic positioning means 42, so that the elastic positioning means can elastically press the edge of the solar battery panel 10.

The set of positioning devices 40 are movable on both sides of the solar battery panel 10, thereby positioning the solar battery panel 10 between two borders 101, 102 of the inspecting region 100. The probe row assembly 30 is driven by a motor screw, a motor cam or a cylinder. The probe row assembly 30 comprises a first probe row 31 and a second probe row 32, both of which are provided in the inspecting region 100. The first probe row 32 and the second probe row 32 press electrode lines 11 on both surfaces of the solar battery panel 10 respectively. After the first probe row 31 and the second probe row 32 are electrically connected with each other, the voltage and current outputted by the solar battery panel 10 can be inspected.

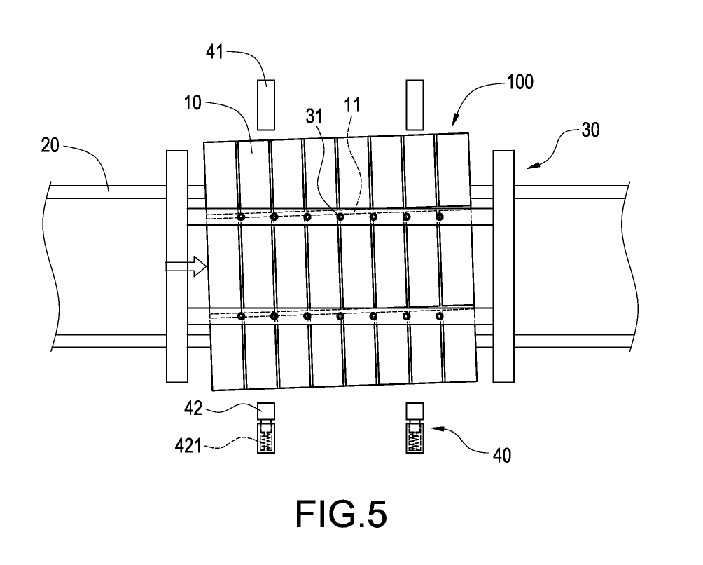

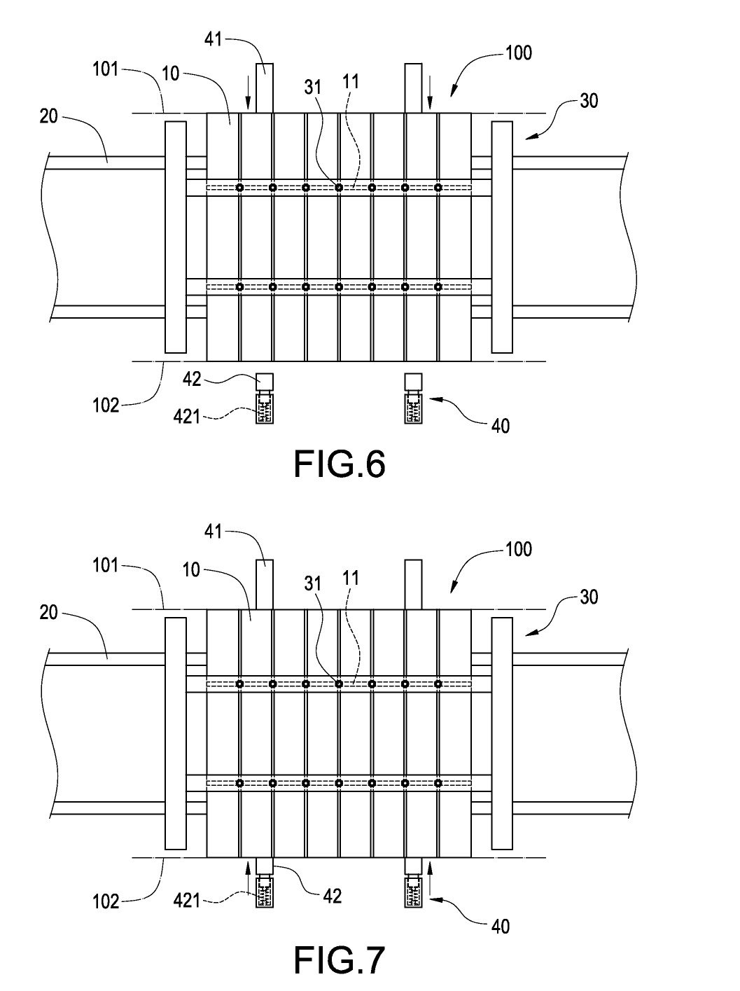

Please refer to FIGS. 5 to 7, which show the positioning procedure of the positioning devices of the present invention. During the inspection, the transport platen 20 transports the solar battery panel 10 to the inspecting region 100 (step 200). At this time, the solar battery panel 10 is oriented oblique, so that the center of the solar battery panel 10 is not aligned with the center of the inspecting region 100. Thus, the set of positioning means 40 are used to re-position the solar battery panel 10 (step 300). First, after the basic positioning means 41 moves to the border 101 of the inspecting region 100, the elastic positioning means 42 moves to elastically push the solar battery panel 10 to the other border 102 of the inspecting region 100. In this way, the electrode lines 11 of the solar battery panel 10 can be positioned to correspond to the positions of the first probe row 31 and the second probe row 32.

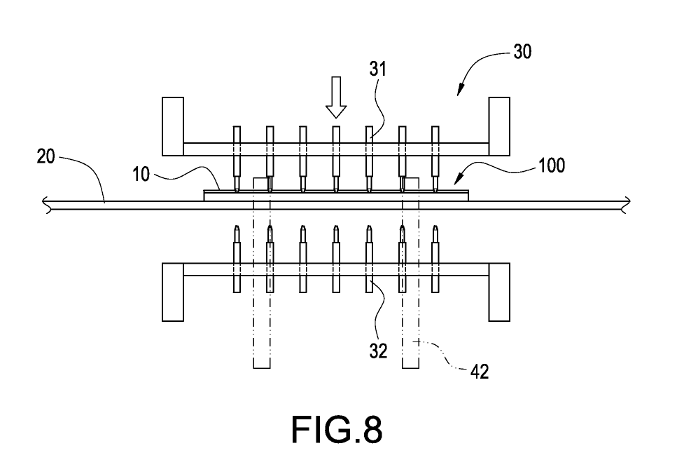

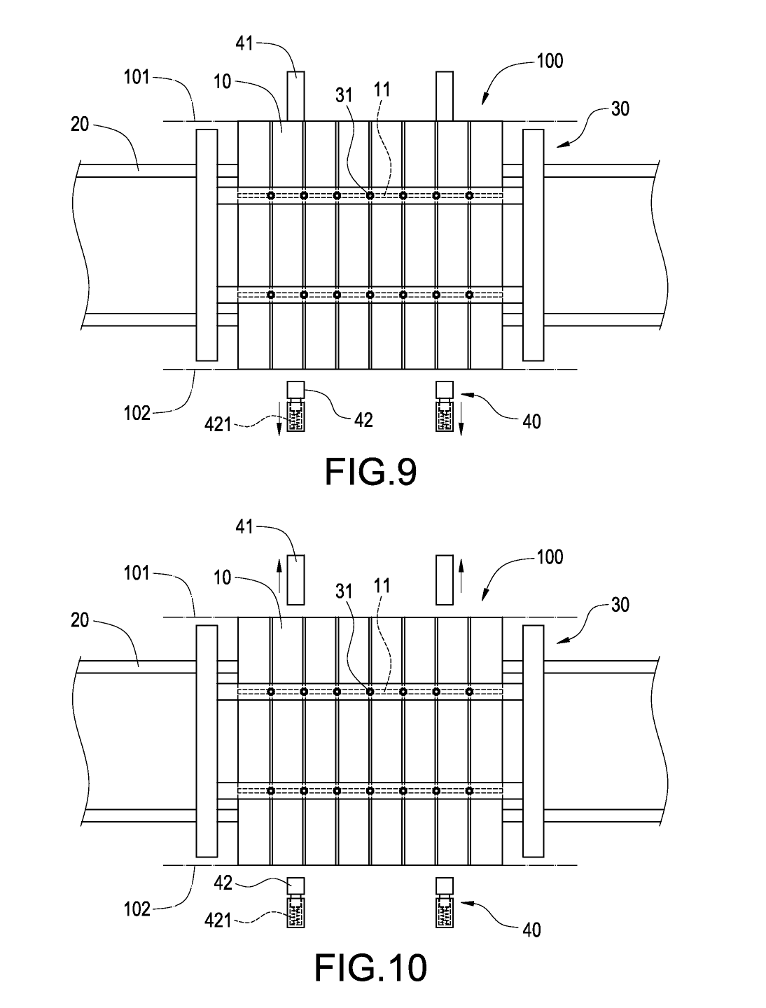

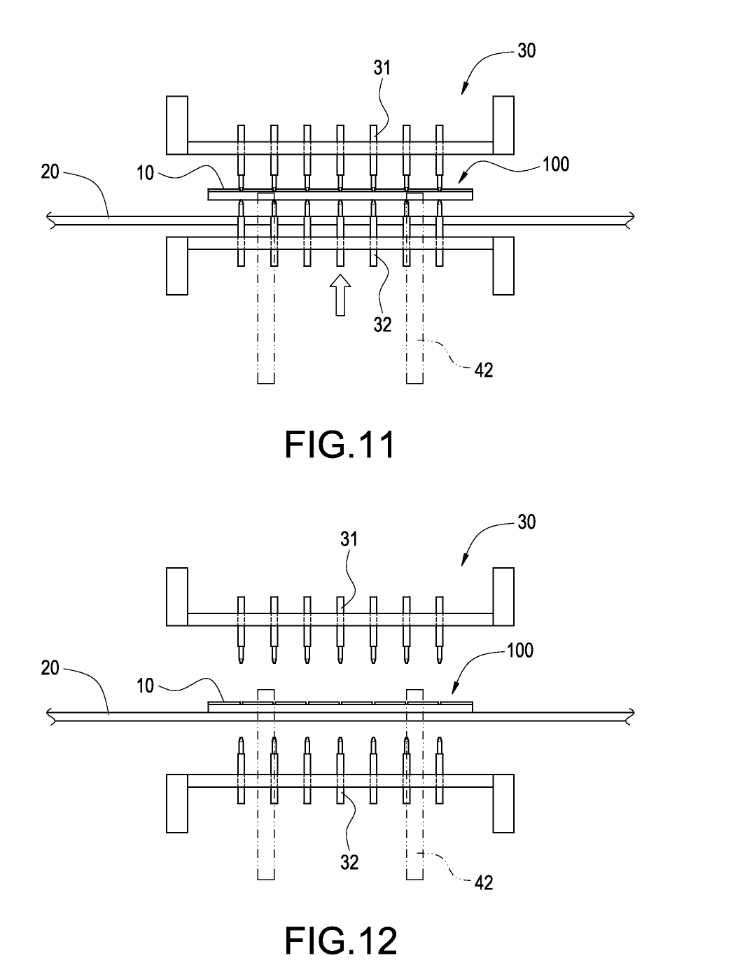

Please refer to FIGS. 8 to 11, which show the pressing inspection of the probe row assembly of the present invention. The first probe row 31 presses downwards to one surface of the solar battery panel 10, so that the first probe row 31 presses the electrode line 11 (step 400) to flatten the solar battery panel 10 and then fix it on the transport platen 20. At this time, the elastic positioning means 42 fixed on one side of the solar battery panel 10 is removed, so that the elastic positioning means 42 does not contact the solar battery panel 10 any more. Then, the basic positioning means 41 on the other side of the solar battery panel 10 is removed (FIG. 10). As a result, both sides of the solar battery panel 10 do not contact the set of positioning devices 40. Next, the second probe row 32 presses upwards to the other surface of the solar battery panel 10, so that the second probe row 32 presses the electrode line 11 on the other surface of the solar battery panel 10 (step 500). With the pressing of the first probe row 31 and the second probe row 32, the solar battery panel 10 can be lifted from the transport platen 20 (FIG. 11), thereby inspecting the voltage and current of the solar battery panel 10.

During the inspection of the voltage and current of the solar battery panel 10, a solar simulator (not shown) is used to emit simulated sunlight that will be absorbed by the solar battery panel 10. Thus, the solar simulator is provided above the inspecting region 100 to illuminate the solar battery panel 10. After the solar battery panel 10 absorbs the simulated sunlight, the first probe row 31 and the second probe row 32 can be electrically connected with each other, thereby inspecting a voltage and a current outputted by the solar battery panel 10.

Finally, please refer to FIG. 12. After the inspection is completed, the first probe row 31 and the second probe row 32 are separated from each other, and the solar battery panel 10 is disposed back on the transport platen 20. The solar battery panel 10 after being inspected completely is transported to a subsequent working region, and next one solar battery panel 10 is transported to the inspecting region 100.

Although the present invention has been described with reference to the foregoing preferred embodiment, it will be understood that the invention is not limited to the details thereof. Various equivalent variations and modifications can still occur to those skilled in this art in view of the teachings of the present invention. Thus, all such variations and equivalent modifications are also embraced within the scope of the invention as defined in the appended claims.

What is claimed is:

1. A positioning method for inspecting a solar battery panel, two opposite surfaces of the solar battery panel being provided with an electrode line respectively, the method including steps of:
a) providing a transport platen, a set of positioning devices, a first probe row and a second probe row;
b) transporting the solar battery panel to an inspecting region by the transport platen;
c) moving the set of positioning devices to position the solar battery panel;
d) the first probe row pressing one surface of the solar battery panel, thereby positioning the first probe row to the electrode line on the surface of the solar battery panel;
e) after the pressing of the first probe row is executed, the second probe row pressing the other surface of the solar battery panel, thereby positioning the second probe row to the electrode line on the other surface of the solar battery panel; and
f) electrically connecting the first probe row and the second probe row to inspect the solar battery panel.

2. The positioning method for inspecting a solar battery panel according to claim 1, wherein the set of positioning devices includes a basic positioning means and an elastic positioning means having an elastic element, the basic positioning means moving to a border of the inspecting region in the step c), and then the elastic positioning means moving to push the solar battery panel to another border to the inspecting region.

3. The positioning method for inspecting a solar battery panel according to claim 1, wherein one surface of the solar battery panel is provided with an electrode line, and the first probe row presses the electrode line on the surface of the solar battery panel in the step d).

4. The positioning method for inspecting a solar battery panel according to claim 1, wherein the other surface of the solar battery panel is provided with another electrode line, and the second probe row presses the other electrode line on the other surface of the solar battery panel in the step e).

5. The positioning method for inspecting a solar battery panel according to claim 2, further including a step d′) of removing the elastic positioning means after the step d), thereby making the elastic positioning means to leave the solar battery panel.

6. The positioning method for inspecting a solar battery panel according to claim 5, further including a step d″) of removing the basic positioning means after the step d′), thereby making the basic positioning means to leave the solar battery panel.

7. The positioning method for inspecting a solar battery panel according to claim 1, wherein the first probe row and the second probe row press the solar battery panel to leave the transport platen in the step f).

8. The positioning method for inspecting a solar battery panel according to claim 1, wherein a solar simulator is further provided in the step a), the step e) is followed by an additional step e′) of emitting light by the solar simulator.

9. A positioning apparatus for inspecting a solar battery panel, two opposite surfaces of the solar battery panel being provided with an electrode line respectively, the inspecting apparatus including:
a transport platen for transporting the solar battery panel to an inspecting region;
a set of positioning devices including a basic positioning means and an elastic positioning means, the set of positioning devices moving on both sides of the solar battery panel to position the solar battery panel into the inspecting region;
a first probe row provided in the inspecting region for pressing the electrode line on one surface of the solar battery panel; and
a second probe row provided in the inspecting region for pressing the electrode line on the other surface of the solar battery panel.

10. The positioning apparatus for inspecting a solar battery panel according to claim 9, wherein the transport platen is one selected from a group constituted of a conveyor platen, a platen driven by a motor screw and a platen driven by a cylinder.

11. The positioning apparatus for inspecting a solar battery panel according to claim 9, wherein the set of positioning devices are selected from a group constituted of a positioning device driven by a motor screw and a positioning device driven by a cylinder.

12. The positioning apparatus for inspecting a solar battery panel according to claim 9, wherein the basic positioning means moves to a border of the inspecting region, and the elastic positioning means moves to another border of the inspecting region and elastically presses the solar battery panel in position.

13. The positioning apparatus for inspecting a solar battery panel according to claim 9, wherein the elastic element is a spring.

14. The positioning apparatus for inspecting a solar battery panel according to claim 9, wherein the first probe row and the second probe row are driven by one of a motor screw, a motor cam and a cylinder.

15. The positioning apparatus for inspecting a solar battery panel according to claim 9, further including a solar simulator provided above the inspecting region to illuminate the solar battery panel.
